(19) United States
(12) Patent Application Publication
(10) Pub. No.: US 2024/0322601 A1
(43) Pub. Date: Sep. 26, 2024

(54) WIRELESS POWER TRANSMITTER THAT CHANGES OPERATION FREQUENCY AND OPERATION METHOD OF THE SAME

(71) Applicant: Electronics and Telecommunications Research Institute, Daejeon (KR)

(72) Inventors: Gwangzeen KO, Daejeon (KR); Sang-Won KIM, Daejeon (KR); Seong-Min KIM, Daejeon (KR); Jung Ick MOON, Daejeon (KR); In Kui CHO, Daejeon (KR)

(21) Appl. No.: 18/611,412

(22) Filed: Mar. 20, 2024

(30) Foreign Application Priority Data
Mar. 24, 2023 (KR) 10-2023-0038433

(51) Int. Cl. H02J 50/12; H02J 50/40

(52) U.S. Cl. CPC H02J 50/12; H02J 50/40

(57) ABSTRACT

A wireless power transmitter that changes an operation frequency and an operation method of the same are provided. The operation method includes controlling the wireless power transmitter to operate at a first operation frequency included in an operation frequency set, changing an operation frequency of the wireless power transmitter from the first operation frequency to a second operation frequency that is different from an operation frequency of a second wireless power transmitter that is adjacent to the wireless power transmitter for every channel duration, and controlling the wireless power transmitter to operate at the second operation frequency.

### CROSS-REFERENCE TO RELATED APPLICATION

This application claims the benefit of Korean Patent Application No. 10-2023-0038433 filed on Mar. 24, 2023, in the Korean Intellectual Property Office, the entire disclosure of which is incorporated herein by reference for all purposes.

### BACKGROUND

### 1. Field of the Invention

One or more embodiments relate to a wireless power transmitter that changes an operation frequency and an operation method of the same.

### 2. Description of the Related Art

Wireless power transfer technology is technology that may convert electrical energy to an electromagnetic wave and transmit energy to a load by radio, without a transmission line. Electrical energy may be converted to a radio frequency (RF) signal of a specific frequency in order to convert the electrical energy to an electromagnetic wave, and the energy may be transmitted using the generated electromagnetic wave. The Wireless power transfer technology includes near-field wireless power transfer technology using a magnetic field and far-field Wireless power transfer technology using an antenna.

### SUMMARY

Embodiments provide a wireless power transmitter that may reduce interference between adjacent wireless power transmitters by changing an operation frequency for every channel duration and an operation method of the same.

According to an aspect, there is provided an operation method of a wireless power transmitter including controlling the wireless power transmitter to operate at a first operation frequency included in an operation frequency set, changing an operation frequency of the wireless power transmitter from the first operation frequency to a second operation frequency that is different from an operation frequency of a second wireless power transmitter that is adjacent to the wireless power transmitter for every channel duration, and controlling the wireless power transmitter to operate at the second operation frequency.

The changing of the operation frequency from the first operation frequency to the second operation frequency may include changing the operation frequency from the first operation frequency to the second operation frequency using an orthogonal sequence.

The operation frequency set may include a greater number of operation frequencies as a number of wireless power transmitters adjacent to the wireless power transmitter increases.

The changing of the operation frequency from the first operation frequency to the second operation frequency may include changing the operation frequency from the first operation frequency to the second operation frequency using an orthogonal sequence that is different from an orthogonal sequence of the second wireless power transmitter.

The wireless power transmitter may include a plurality of capacitors matching each of operation frequencies included in the operation frequency set and a plurality of switches connected to the plurality of capacitors.

The changing of the operation frequency from the first operation frequency to the second operation frequency may include turning off a first switch connected to a first capacitor matching the first operation frequency and turning on a second switch connected to a second capacitor matching the second operation frequency.

The changing of the operation frequency from the first operation frequency to the second operation frequency may include changing the operation frequency from the first operation frequency to the second operation frequency based on a phase of the first operation frequency and a phase of the second operation frequency.

The changing of the operation frequency from the first operation frequency to the second operation frequency may include tracking the phase of the first operation frequency during the channel duration and matching an end phase of the first operation frequency with a start phase of the second operation frequency when the operation frequency is changed from the first operation frequency to the second operation frequency.

The changing of the operation frequency from the first operation frequency to the second operation frequency may include changing the operation frequency from the first operation frequency to the second operation frequency based on a signal amplitude of the first operation frequency and a signal amplitude of the second operation frequency.

The changing of the operation frequency from the first operation frequency to the second operation frequency may include matching an end signal amplitude of the first operation frequency and a start signal amplitude of the second operation frequency to 0.

The changing of the operation frequency from the first operation frequency to the second operation frequency may include controlling a duty cycle of a signal amplitude pulse corresponding to the end signal amplitude of the first operation frequency to 0.

The channel duration may include a rising duration, a falling duration, and a steady duration. The changing of the operation frequency from the first operation frequency to the second operation frequency may include controlling, in the rising duration, the signal amplitude of the first operation frequency to reach a target signal amplitude from a start signal amplitude of 0, controlling, in the steady duration, the signal amplitude of the first operation frequency to maintain the target signal amplitude, and controlling, in the falling duration, the signal amplitude of the first operation frequency to decrease from the target signal amplitude to 0.

The changing of the operation frequency from the first operation frequency to the second operation frequency may include controlling, in the rising duration, a duty cycle of a signal amplitude pulse to increase from 0 to a target duty cycle and controlling, in the falling duration, a duty cycle of a signal amplitude pulse to decrease from the target duty cycle to 0.

According to an aspect, there is provided an operation method of a wireless power transmitter including controlling the wireless power transmitter to operate at a first operation frequency, changing an operation frequency of the wireless power transmitter from the first operation frequency to a second operation frequency based on a signal amplitude of the first operation frequency or a phase of the first operation frequency at an end timepoint of a channel duration, wherein the channel duration is a cycle of changing an operation frequency of the wireless power transmitter, and controlling the wireless power transmitter to operate at the second operation frequency.

According to an aspect, there is provided a wireless power transmitter including a controller configured to control the wireless power transmitter to operate at a first operation frequency included in an operation frequency set, change an operation frequency of the wireless power transmitter from the first operation frequency to a second operation frequency that is different from an operation frequency of a second wireless power transmitter that is adjacent to the wireless power transmitter for every channel duration, and control the wireless power transmitter to operate at the second operation frequency, and a transmitting coil configured to transmit power at the first operation frequency or the second operation frequency.

The controller may change the operation frequency from the first operation frequency to the second operation frequency using an orthogonal sequence.

The controller may change the operation frequency from the first operation frequency to the second operation frequency based on a phase of the first operation frequency and a phase of the second operation frequency.

The controller may track the phase of the first operation frequency during the channel duration and match an end phase of the first operation frequency with a start phase of the second operation frequency when the operation frequency is changed from the first operation frequency to the second operation frequency.

The controller may change the operation frequency from the first operation frequency to the second operation frequency based on a signal amplitude of the first operation frequency and a signal amplitude of the second operation frequency.

The controller may match an end signal amplitude of the first operation frequency and a start signal amplitude of the second operation frequency to 0.

Additional aspects of embodiments will be set forth in part in the description which follows and, in part, will be apparent from the description, or may be learned by practice of the disclosure.

According to embodiments, interference between adjacent wireless power transmitters may be reduced by changing an operation frequency of a wireless power transmitter for every channel duration.

### BRIEF DESCRIPTION OF THE DRAWINGS

These and/or other aspects, features, and advantages of the invention will become apparent and more readily appreciated from the following description of embodiments, taken in conjunction with the accompanying drawings of which:

FIG. 1 is a diagram illustrating a wireless charging system;

FIG. 2 is a diagram illustrating a case in which two or more wireless power transmitters are present;

FIG. 3 is a diagram illustrating operation frequency hopping according to an embodiment;

FIG. 4 is a diagram illustrating frequency hopping in a case in which two or more wireless power transmitters are present, according to an embodiment;

FIG. 5 is a diagram illustrating a wireless power transmitter according to an embodiment;

FIG. 6 is a flowchart illustrating an operation of a wireless power transmitter, according to an embodiment;

FIG. 7 is a diagram illustrating phase discontinuity that may occur in operation frequency hopping;

FIGS. 8 and 9 are diagrams illustrating phase matching operation frequency hopping according to an embodiment;

FIGS. 10 and 11 are diagrams illustrating pulse matching operation frequency hopping according to an embodiment; and

FIG. 12 is a flowchart illustrating an operation of a wireless power transmitter, according to an embodiment.

### DETAILED DESCRIPTION

Hereinafter, embodiments are described in detail with reference to the accompanying drawings. The scope of the right, however, should not be construed as limited to the embodiments set forth herein. In the drawings, like reference numerals are used for like elements.

Various modifications may be made to the embodiments. Here, the embodiments are not construed as limited to the disclosure and should be understood to include all changes, equivalents, and replacements within the idea and the technical scope of the disclosure.

Although terms such as “first” or “second” are used to explain various components, the components are not limited to the terms. These terms should be used only to distinguish one component from another component. For example, a first component may be referred to as a second component, and similarly the second component may also be referred to as the first component.

The terminology used herein is for the purpose of describing particular embodiments only and is not intended to limit the embodiments. The singular forms “a,” “an,” and “the” are intended to include the plural forms as well, unless the context clearly indicates otherwise. As used herein, each of phrases such as “A or B,” “at least one of A and B,” “at least one of A or B,” “A, B, or C,” “at least one of A, B, and C,” and “at least one of A, B, or C” may include any one of the items listed in the corresponding one of the phrases or all possible combinations thereof. It should be further understood that the terms “comprises/comprising” and/or “includes/including,” when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical or scientific terms used herein have the same meaning as those commonly understood by one of ordinary skill in the art to which the embodiments belong. Terms, such as those defined in commonly used dictionaries, are to be interpreted as having a meaning that is consistent with their meaning in the context of the relevant art and the present disclosure, and are not to be interpreted in an idealized or overly formal sense unless expressly so defined herein.

When describing the embodiments with reference to the accompanying drawings, like reference numerals refer to like components and a repeated description related thereto is omitted. In the description of embodiments, detailed description of well-known related structures or functions is omitted when it is deemed that such description may cause ambiguous interpretation of the present disclosure.

Hereinafter, embodiments are described in detail with reference to the accompanying drawings.

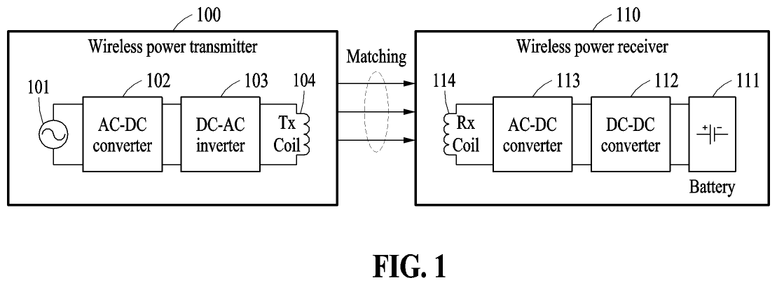

FIG. 1 is a diagram illustrating a wireless charging system.

Referring to FIG. 1, a wireless charging system including one wireless power transmitter 100 and one wireless power receiver 110 is shown.

The wireless power transmitter 100 may include a power source 101, an alternating current (AC)-direct current (DC) converter 102, a DC-AC inverter 103, and a transmitting coil 104. The wireless power receiver 110 may include a battery 111, a DC-DC converter 112, an AC-DC converter 113, and a receiving coil 114.

The wireless charging system may charge the battery 111 by transmitting power through magnetic induction of the transmitting coil 104 and the receiving coil 114. The amount of power transmitted to the transmitting coil 104 and the receiving coil 114 may vary depending on the capacity and charging speed of the battery 111. Accordingly, the DC-AC inverter 103 in the wireless power transmitter 100 may be designed according to the transmitted power. In addition, the AC-DC converter 102 may be needed to supply appropriate voltage and current to the DC-AC inverter 103. The AC-DC converter 102 may perform AC-DC power conversion in the front end of the DC-AC inverter 103.

Similarly, alternating current induced in the receiving coil 114 may be converted to direct current through the AC-DC converter 113. Subsequently, the DC-DC converter 112 may convert the received power to required voltage and current to charge the battery 111.

In order to transmit power in the wireless charging system, matching a resonant frequency of the wireless power transmitter 100 with a resonant frequency of the wireless power receiver 110 may be needed. When the matching is imperfect, the efficiency of the wireless charging system may decrease and interference may occur.

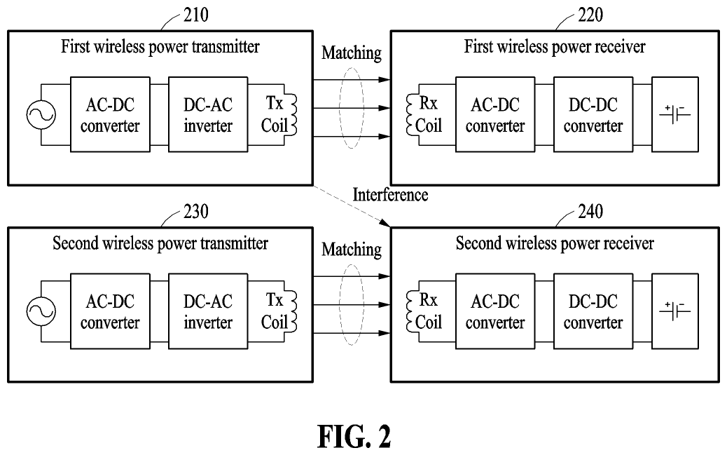

FIG. 2 is a diagram illustrating a case in which two or more wireless power transmitters are present.

Referring to FIG. 2, a wireless charging system including two wireless power transmitters and two wireless power receivers is shown.

There may be a case in which two or more wireless power transmitters operate simultaneously. In this case, the two or more wireless power transmitters may use the same resonant frequency. For example, a first wireless power transmitter 210 and a second wireless power transmitter 230 may use the same resonant frequency to charge a first wireless power receiver 220 and a second wireless power receiver 240, respectively.

In this case, mutual inductance may be induced from the first wireless power transmitter 210 to the second wireless power receiver 240. Therefore, the mutual inductance, which is interference, may affect resonant frequency matching, thereby reducing the efficiency of the wireless charging system.

Hereinafter, a method of controlling an operation frequency (i.e., a resonant frequency) without changing the structure of a wireless power transmitter and/or a wireless power receiver in order to reduce interference caused by the mutual inductance described above and interference caused by resonant frequency mismatch due to the mutual inductance is described.

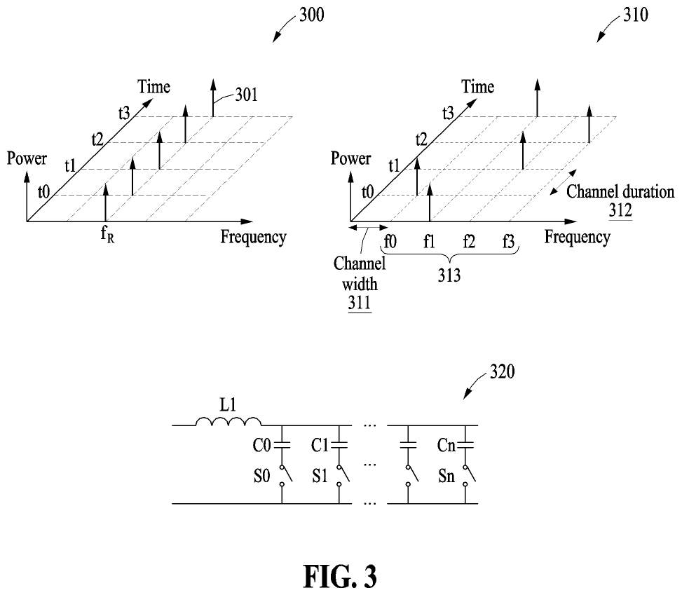

FIG. 3 is a diagram illustrating operation frequency hopping according to an embodiment.

Referring to FIG. 3, a diagram 300 illustrating an operation frequency 301 of a conventional wireless power transmitter in the time domain is shown. Referring to the diagram 300, the conventional wireless power transmitter may keep the operation frequency 301 constant without changing the operation frequency 301 in the time domain. In the diagram 300, the operation frequency 301 is expressed discontinuously for ease of description, but it is obvious to one of ordinary skill in the art that the operation frequency 301 operates continuously in the time domain.

Referring to FIG. 3, a diagram 310 illustrating a change of an operation frequency is shown. Referring to the diagram 310, a wireless power transmitter may operate by selecting one operation frequency from an operation frequency set 313 including “N” operation frequency candidates. The operation frequency may be referred to as a channel. Therefore, the “N” operation frequency candidates may be located at intervals of a channel width 311. The wireless power transmitter may operate at one of the operation frequency candidates included in the operation frequency set 313 and, after a channel duration 312 passes, may operate at another of the operation frequency candidates. The operation of the wireless power transmitter described above may be controlled by a controller of the wireless power transmitter. The change of the operation frequency of the wireless power transmitter that occurs for every channel duration 312 may be referred to as operation frequency hopping.

For example, the wireless power transmitter may operate by selecting f1 from the operation frequency set 313 including operation frequencies f0, f1, f2, and f3. After the channel duration 312 passes, the wireless power transmitter may change the operation frequency and operate at f0.

That is, by changing the operation frequency of the wireless power transmitter for every channel duration, interference may be reduced compared to when using a single operation frequency. In other words, by changing the operation frequency of the wireless power transmitter to one of “N” operation frequency candidates for every channel duration, the channel occupancy rate may be reduced to 1/N compared to when using one operation frequency. Accordingly, channel interference may be reduced to 1/N, thereby increasing a processing gain.

Referring to FIG. 3, a diagram 320 illustrating a method in which the wireless power transmitter changes the operation frequency is shown. The wireless power transmitter may include a plurality of capacitors and switches connected to the plurality of capacitors.

Referring to the diagram 320, the plurality of capacitors and the switches connected to the plurality of capacitors are shown. For example, capacitors C0 to Cn may be respectively connected to switches S0 to Sn. Each of the capacitors C0 to Cn may be matched with operation frequency candidates included in the operation frequency set 313. For example, each of the capacitors C0 to Cn may be matched with operation frequency candidates f0 to fn.

The controller of the wireless power transmitter may control the switches connected to the capacitors. That is, the controller may control the operation frequency by turning on/off the switches connected to the capacitors. The controller may control the operation frequency by turning on/off the switches connected to the capacitors for every channel duration. The controller may change the operation frequency for every channel duration by turning off a first switch connected to a first capacitor matching a first operation frequency, which is the current operation frequency, and turning on a second switch connected to a second capacitor matching a second operation frequency.

By the controller changing the operation frequency of the wireless power transmitter between the operation frequency candidates f0 to fn, the channel occupancy rate may be reduced. In other words, when the controller changes the operation frequency of the wireless power transmitter between four operation frequency candidates, the channel occupancy rate may be reduced to ¼. Accordingly, interference in the corresponding channel may also be reduced to ¼. Therefore, the processing gain may increase compared to the case in which the wireless power transmitter does not change the operation frequency.

Hereinafter, an operation method of each of two or more wireless power transmitters adjacent to each other is described.

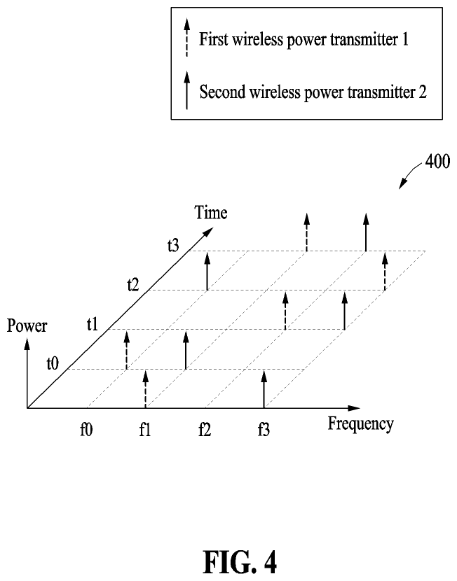

FIG. 4 is a diagram 400 illustrating frequency hopping in a case in which two or more wireless power transmitters are present, according to an embodiment.

Referring to the diagram 400, changes in operation frequencies of a first wireless power transmitter and a second wireless power transmitter over time are shown. The second wireless power transmitter may be adjacent to the first wireless power transmitter. When the first wireless power transmitter and the second wireless power transmitter operate at the same operation frequency, interference may occur due to mutual inductance.

Thus, the first wireless power transmitter and the second wireless power transmitter may perform an operation frequency change as described with reference to FIG. 3 to avoid interference.

Specifically, the first wireless power transmitter and the second wireless power transmitter may change their operation frequencies using different orthogonal sequences for every channel duration. Here, the first wireless power transmitter and the second wireless power transmitter may change their operation frequencies to operation frequencies different from each other.

For example, the first wireless power transmitter may change the operation frequency from f0 to f2 at a time t1, and the second wireless power transmitter may change the operation frequency from f1 to f3 at the time t1.

When there are “N” operation frequency candidates, up to “N” wireless power transmitters may be adjacent to each other. The up to “N” wireless power transmitters may change their operation frequencies for every channel duration using different orthogonal sequences. However, as the number of adjacent wireless power transmitters increases, the processing gain may decrease. Thus, to increase the processing gain, an operation frequency set may include more operation frequency candidates as the number of wireless power transmitters adjacent to one wireless power transmitter increases.

Hereinafter, a wireless power transmitter that changes the operation frequency is described.

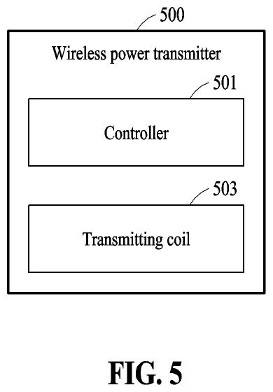

FIG. 5 is a diagram illustrating a wireless power transmitter according to an embodiment.

Referring to FIG. 5, a wireless power transmitter 500 is shown. The wireless power transmitter 500 may include a controller 501 and a transmitting coil 503. In the wireless power transmitter 500 of FIG. 1, only the components related to the embodiment described herein are shown. Therefore, it is obvious to one of ordinary skill in the art that the wireless power transmitter 500 may further include other general-purpose components in addition to the components shown in FIG. 5.

The controller 501 may control the operation of the wireless power transmitter 500. The controller 501 may control the wireless power transmitter 500 by controlling other components. For example, the controller 501 may control an AC-DC converter (not shown). The controller 501 may change an operation frequency by controlling a switch connected to a capacitor matching the operation frequency.

The transmitting coil 503 may transmit power to a receiving coil of a wireless power receiver (not shown) through magnetic induction. The transmitting coil 503 may be controlled by the controller 501. The transmitting coil 503 may transmit power to the wireless power receiver at an operation frequency obtained after an operation frequency change by the controller 501.

The operation of the wireless power transmitter 500 described above and the operation of the wireless power transmitter 500 described below may be performed by the controller 501. The controller 501 may change the operation frequency of the wireless power transmitter 500 for every channel duration. The controller 501 may change the operation frequency of the wireless power transmitter 500 for every channel duration based on an orthogonal sequence. The controller 501 may change the operation frequency to an operation frequency that is different from an operation frequency of other adjacent wireless power transmitters based on the orthogonal sequence.

Hereinafter, an operation of a wireless power transmitter is described with reference to a flowchart.

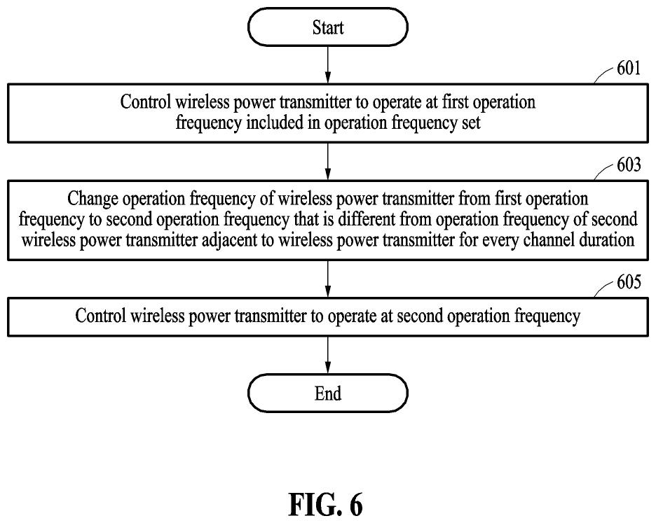

FIG. 6 is a flowchart illustrating an operation of a wireless power transmitter, according to an embodiment.

In the following embodiment, operations may be performed sequentially, but not necessarily. For example, the order of the operations may be changed, and at least two of the operations may be performed in parallel. Operations 601 to 605 may be performed by a controller of the wireless power transmitter described below, but the embodiments are not limited thereto.

In operation 601, the controller may control the wireless power transmitter to operate at a first operation frequency included in an operation frequency set.

In operation 603, the controller may change an operation frequency of the wireless power transmitter from the first operation frequency to a second operation frequency that is different from an operation frequency of a second wireless power transmitter adjacent to the wireless power transmitter for every channel duration.

In operation 605, the controller may control the wireless power transmitter to operate at the second operation frequency.

Hereinafter, phase discontinuity that may occur when changing the operation frequency from the first operation frequency to the second operation frequency is described.

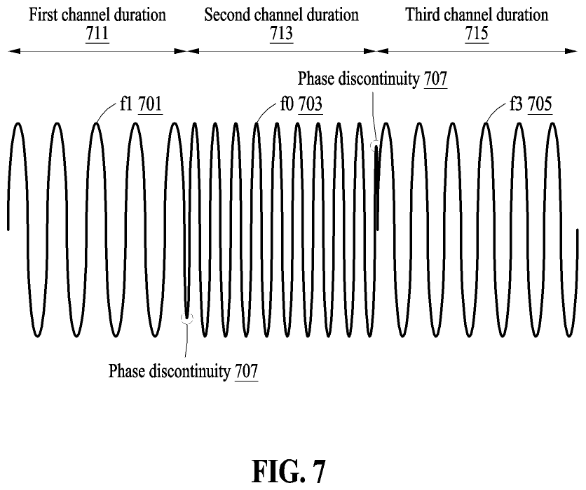

FIG. 7 is a diagram illustrating phase discontinuity that may occur in operation frequency hopping.

Referring to FIG. 7, a wireless power transmitter may operate at an operation frequency f1 701 in a first channel duration 711, operate at an operation frequency f0 703 in a second channel duration 713, and operate at an operation frequency f3 705 in a third channel duration 715. That is, the operation frequency may change from the operation frequency f1 701 to the operation frequency f0 703 between the first channel duration 711 and the second channel duration 713. The operation frequency may change from the operation frequency f0 703 to the operation frequency f3 705 between the second channel duration 713 and the third channel duration 715. The operation frequencies f1 701, the f0 703, and the f3 705 may be included in an operation frequency set as a portion of operation frequency candidates.

Here, the channel duration and the duration of the operation frequency may not match each other. Thus, since the channel duration and the operation frequency duration do not match each other, phase discontinuity 707 may occur. When the phase discontinuity 707 occurs, high frequencies may occur in the frequency domain. High frequencies may cause hopping interference between frequencies.

Hereinafter, therefore, a method of removing phase discontinuity when changing the channel duration is described.

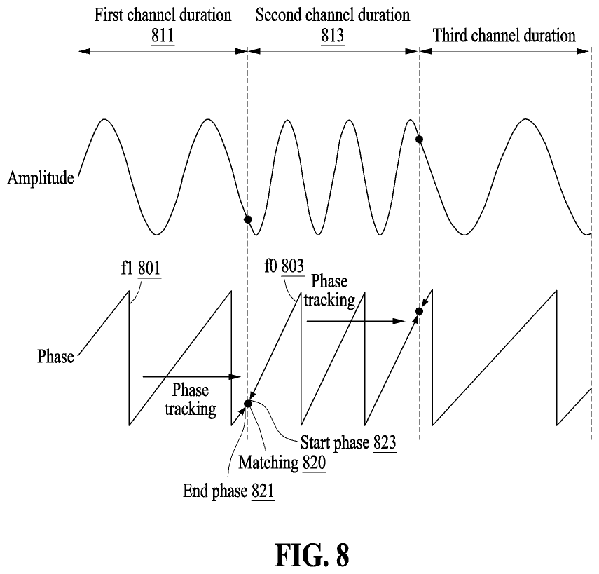

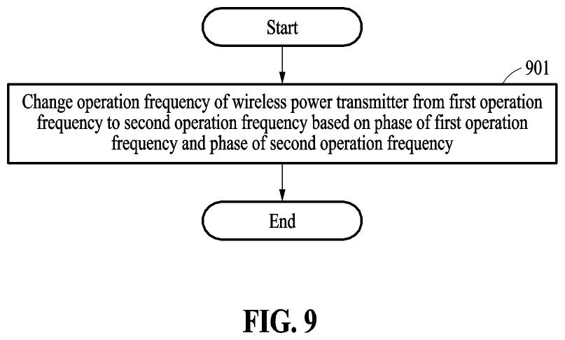

FIGS. 8 and 9 are diagrams illustrating phase matching operation frequency hopping according to an embodiment.

According to an embodiment, the phase matching operation frequency hopping may be used to remove the phase discontinuity described above.

Referring to FIG. 8, a diagram illustrating the phase matching operation frequency hopping is shown. Hereinafter, an operation frequency f1 is assumed to be a first operation frequency, and an operation frequency f0 is assumed to be a second operation frequency.

A controller may change an operation frequency of a wireless power transmitter from the first operation frequency to the second operation frequency based on a phase 801 of the first operation frequency and a phase 803 of the second operation frequency.

The controller may track a phase during a channel duration. The controller may track the phase during one channel duration and thus detect an end phase of an operation frequency of a point at which the channel duration ends. In other words, the controller may track the phase during a first channel duration 811 and detect an end phase 821 of the first operation frequency of the point at which the first channel duration 811 ends.

The controller may match 820 a start phase of the operation frequency of the point at which a subsequent channel duration starts with an end phase of the operation frequency of the point at which a previous channel duration ends. In other words, the controller may match 820 a start phase 823 of the second operation frequency of the point at which a second channel duration 813 starts with the end phase 821 of the first operation frequency of the point at which the first channel duration 811 ends.

By matching the end phase 821 of the first operation frequency with the start phase 823 of the second operation frequency, the controller may remove hopping interference due to phase discontinuity.

Referring to FIG. 9, a flowchart illustrating a method in which a controller performs phase matching operation frequency hopping is shown.

In operation 901, the controller may change an operation frequency of a wireless power transmitter from a first operation frequency to a second operation frequency based on a phase of the first operation frequency and a phase of the second operation frequency.

Specifically, the controller may track the phase of the first operation frequency during a first channel duration. When changing the operation frequency from the first operation frequency to the second operation frequency, the controller may match an end phase of the first operation frequency with a start phase of the second operation frequency.

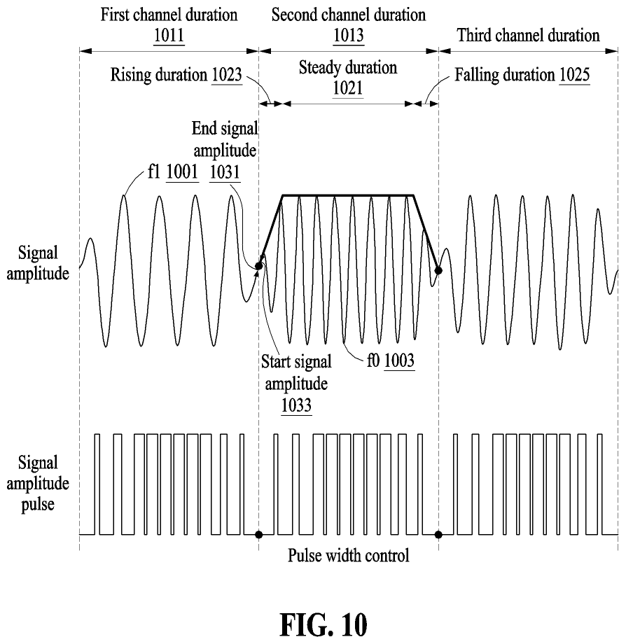

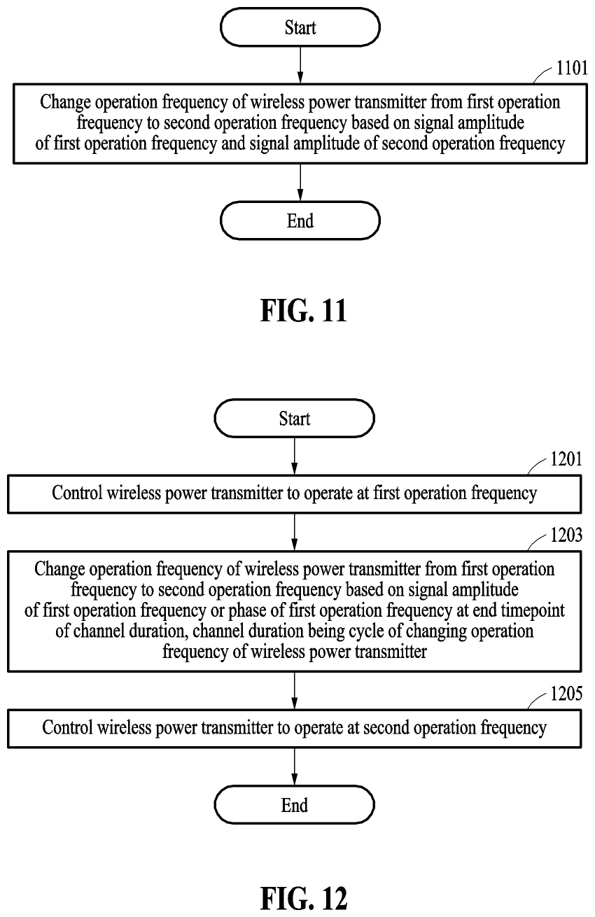

FIGS. 10 and 11 are diagrams illustrating pulse matching operation frequency hopping according to an embodiment.

According to an embodiment, the pulse matching operation frequency hopping may be used to remove the phase discontinuity described above.

Referring to FIG. 10, a diagram illustrating the pulse matching operation frequency hopping is shown. Hereinafter, an operation frequency f1 is assumed to be a first operation frequency, and an operation frequency f0 is assumed to be a second operation frequency.

A controller may change an operation frequency from the first operation frequency to the second operation frequency based on a signal amplitude 1001 of the first operation frequency and a signal amplitude 1003 of the second operation frequency. The controller may reduce the signal amplitude of the operation frequency to 0 for every channel duration. In other words, the controller may reduce an end signal amplitude 1031 of the operation frequency to 0 at the point at which a channel duration ends. The controller may reduce the end signal amplitude 1031 of the first operation frequency to 0 at the point at which a first channel duration 1011 ends.

The controller may control a start signal amplitude 1033 of the second operation frequency of the point at which a second channel duration 1013 starts to 0. That is, the controller may match the end signal amplitude 1031 of the first operation frequency and the start signal amplitude 1033 of the second operation frequency to 0.

Subsequently, the controller may control the signal amplitude 1003 of the second operation frequency to increase to a target signal amplitude. When the signal amplitude 1003 of the second operation frequency reaches the target signal amplitude, the controller may control the signal amplitude 1003 of the second operation frequency to maintain the target signal amplitude. The controller may control the signal amplitude 1003 of the second operation frequency to maintain the target signal amplitude and subsequently decrease back to 0.

The channel duration may include a rising duration 1023 in which the signal amplitude increases from 0 to the target signal amplitude, a steady duration 1021 in which the signal amplitude maintains the target signal amplitude, and a falling duration 1025 in which the signal amplitude decreases from the target signal amplitude to 0. The controller may increase the signal amplitude of the operation frequency from 0 to the target signal amplitude during the rising duration 1023. The controller may maintain the signal amplitude of the operation frequency at the target signal amplitude during the steady duration 1021. The controller may reduce the signal amplitude of the operation frequency from the target signal amplitude to 0 during the falling duration 1025.

The controller may control the signal amplitude pulse, which controls the signal amplitude, to be 0 at every point at which the channel duration ends. In other words, the controller may control a duty cycle of a signal amplitude pulse corresponding to the end signal amplitude 1031 of the first operation frequency to 0. The controller may control a duty cycle of a signal amplitude pulse corresponding to the start signal amplitude 1033 of the second operation frequency to 0.

The controller may increase the duty cycle of the signal amplitude pulse from 0 to a target duty cycle in the rising duration 1023. The controller may maintain the duty cycle of the signal amplitude pulse at the target duty cycle in the steady duration 1021. The controller may reduce the duty cycle of the signal amplitude pulse from the target duty cycle to 0 in the falling duration 1025.

Ultimately, the controller may control the signal amplitude at the point of changing the operation frequency to 0 to eliminate the phase difference between the first operation frequency and the second operation frequency. Here, the rising duration 1023 and the falling duration 1025 may not have a significant effect on the efficiency of Wireless power transfer even when the signal amplitude decreases to 1 to 2 wavelengths of the duration of the operation frequency.

Referring to FIG. 11, a flowchart illustrating a method in which a controller performs pulse matching operation frequency hopping is shown.

In operation 1101, the controller may change the operation frequency of a wireless power transmitter from the first operation frequency to the second operation frequency based on the signal amplitude of the first operation frequency and the signal amplitude of the second operation frequency.

The controller may match the end signal amplitude of the first operation frequency and the start signal amplitude of the second operation frequency to 0.

The controller may control a duty cycle of a signal amplitude pulse corresponding to the end signal amplitude of the first operation frequency to 0.

The controller may control the duty cycle of the signal amplitude pulse to increase from 0 to the target duty cycle in the rising duration. The controller may control the duty cycle of the signal amplitude pulse to decrease from the target duty cycle to 0 in the falling duration.

FIG. 12 is a flowchart illustrating an operation of a wireless power transmitter, according to an embodiment.

In the following embodiment, operations may be performed sequentially, but not necessarily. For example, the order of the operations may be changed, and at least two of the operations may be performed in parallel. Operations 1201 to 1205 may be performed by a controller of the wireless power transmitter, but the embodiments are not limited thereto.

In operation 1201, the controller may control the wireless power transmitter to operate at a first operation frequency.

In operation 1203, the controller may change an operation frequency of the wireless power transmitter from the first operation frequency to the second operation frequency based on a signal amplitude of the first operation frequency or a phase of the first operation frequency at an end timepoint of a channel duration. The channel duration may be a cycle of changing the operation frequency of the wireless power transmitter.

In operation 1205, the controller may control the wireless power transmitter to operate at the second operation frequency.

The components described in the embodiments may be implemented by hardware components including, for example, at least one digital signal processor (DSP), a processor, a controller, an application-specific integrated circuit (ASIC), a programmable logic element, such as a field programmable gate array (FPGA), other electronic devices, or combinations thereof. At least some of the functions or the processes described in the embodiments may be implemented by software, and the software may be recorded on a recording medium. The components, the functions, and the processes described in the embodiments may be implemented by a combination of hardware and software.

The method according to the present disclosure may be written in a computer-executable program and may be implemented as various recording media such as magnetic storage media, optical reading media, or digital storage media.

Various techniques described herein may be implemented in digital electronic circuitry, computer hardware, firmware, software, or combinations thereof. The implementations may be achieved as a computer program product, for example, a computer program tangibly embodied in a machine-readable storage device (a computer-readable medium) to process the operations of a data processing device, for example, a programmable processor, a computer, or a plurality of computers or to control the operations. A computer program, such as the computer program(s) described above, may be written in any form of a programming language, including compiled or interpreted languages, and may be deployed in any form, including as a stand-alone program or as a module, a component, a subroutine, or other units suitable for use in a computing environment. A computer program may be deployed to be processed on one computer or multiple computers at one site or distributed across multiple sites and interconnected by a communication network.

Processors suitable for processing of a computer program include, by way of example, both general and special-purpose microprocessors, and any one or more processors of any type of digital computer. Generally, a processor will receive instructions and data from read-only memory (ROM) or random-access memory (RAM), or both. Elements of a computer may include at least one processor for executing instructions and one or more memory devices for storing instructions and data. Generally, a computer may also include, or be operatively coupled to receive data from or transfer data to, or both, one or more mass storage devices for storing data, e.g., magnetic, magneto-optical disks, or optical disks. Examples of information carriers suitable for embodying computer program instructions and data include semiconductor memory devices, for example, magnetic media such as hard disks, floppy disks, and magnetic tape, optical media such as compact disc ROM (CD-ROM) or a digital versatile disc (DVD), magneto-optical media such as floptical disks, ROM, RAM, flash memory, erasable programmable ROM (EPROM), or electrically erasable programmable ROM (EEPROM). The processor and the memory may be supplemented by, or incorporated in, special-purpose logic circuitry.

In addition, non-transitory computer-readable media may be any available media that may be accessed by a computer and may include both computer storage media and transmission media.

Although the present specification includes details of a plurality of specific embodiments, the details should not be construed as limiting any invention or a scope that can be claimed, but rather should be construed as being descriptions of features that may be peculiar to specific embodiments of specific inventions. Specific features described in the present specification in the context of individual embodiments may be combined and implemented in a single embodiment. On the contrary, various features described in the context of a single embodiment may be implemented in a plurality of embodiments individually or in any appropriate sub-combination. Moreover, although features may be described above as acting in specific combinations and even initially claimed as such, one or more features from a claimed combination can in some cases be excised from the combination, and the claimed combination may be changed to a sub-combination or a modification of a sub-combination.

Likewise, although operations are depicted in a predetermined order in the drawings, it should not be construed that the operations need to be performed sequentially or in the predetermined order, which is illustrated to obtain a desirable result, or that all of the shown operations need to be performed. In specific cases, multi-tasking and parallel processing may be advantageous. In addition, it should not be construed that the separation of various device components of the aforementioned embodiments is required in all types of embodiments, and it should be understood that the described program components and devices are generally integrated as a single software product or packaged into a multiple-software product.

The embodiments disclosed in the present specification and the drawings are intended merely to present specific examples in order to aid in understanding of the present disclosure, but are not intended to limit the scope of the present disclosure. It will be apparent to one of ordinary skill in the art that, in addition to the disclosed embodiments, various other examples modified based on the technical spirit of the present disclosure may be implemented.

What is claimed is:

1. An operation method of a wireless power transmitter, the operation method comprising:
controlling the wireless power transmitter to operate at a first operation frequency included in an operation frequency set;
changing an operation frequency of the wireless power transmitter from the first operation frequency to a second operation frequency that is different from an operation frequency of a second wireless power transmitter that is adjacent to the wireless power transmitter for every channel duration; and
controlling the wireless power transmitter to operate at the second operation frequency.

2. The operation method of claim 1, wherein the changing of the operation frequency from the first operation frequency to the second operation frequency comprises:
changing the operation frequency from the first operation frequency to the second operation frequency using an orthogonal sequence.

3. The operation method of claim 1, wherein the operation frequency set comprises:
a greater number of operation frequencies as a number of wireless power transmitters adjacent to the wireless power transmitter increases.

4. The operation method of claim 1, wherein the changing of the operation frequency from the first operation frequency to the second operation frequency comprises:
changing the operation frequency from the first operation frequency to the second operation frequency using an orthogonal sequence that is different from an orthogonal sequence of the second wireless power transmitter.

5. The operation method of claim 1, wherein the wireless power transmitter comprises:
a plurality of capacitors matching each of operation frequencies included in the operation frequency set; and
a plurality of switches connected to the plurality of capacitors.

6. The operation method of claim 5, wherein the changing of the operation frequency from the first operation frequency to the second operation frequency comprises:
turning off a first switch connected to a first capacitor matching the first operation frequency; and
turning on a second switch connected to a second capacitor matching the second operation frequency.

7. The operation method of claim 1, wherein the changing of the operation frequency from the first operation frequency to the second operation frequency comprises:
changing the operation frequency from the first operation frequency to the second operation frequency based on a phase of the first operation frequency and a phase of the second operation frequency.

8. The operation method of claim 7, wherein the changing of the operation frequency from the first operation frequency to the second operation frequency comprises:
tracking the phase of the first operation frequency during the channel duration; and
matching an end phase of the first operation frequency with a start phase of the second operation frequency when the operation frequency is changed from the first operation frequency to the second operation frequency.

9. The operation method of claim 1, wherein the changing of the operation frequency from the first operation frequency to the second operation frequency comprises:
changing the operation frequency from the first operation frequency to the second operation frequency based on a signal amplitude of the first operation frequency and a signal amplitude of the second operation frequency.

10. The operation method of claim 9, wherein the changing of the operation frequency from the first operation frequency to the second operation frequency comprises:
matching an end signal amplitude of the first operation frequency and a start signal amplitude of the second operation frequency to 0.

11. The operation method of claim 9, wherein the changing of the operation frequency from the first operation frequency to the second operation frequency comprises:
controlling a duty cycle of a signal amplitude pulse corresponding to the end signal amplitude of the first operation frequency to 0.

12. The operation method of claim 9, wherein
the channel duration comprises:
a rising duration;
a falling duration; and
a steady duration, and
the changing of the operation frequency from the first operation frequency to the second operation frequency comprises:
controlling, in the rising duration, the signal amplitude of the first operation frequency to reach a target signal amplitude from a start signal amplitude of 0;
controlling, in the steady duration, the signal amplitude of the first operation frequency to maintain the target signal amplitude; and
controlling, in the falling duration, the signal amplitude of the first operation frequency to decrease from the target signal amplitude to 0.

13. The operation method of claim 12, wherein the changing of the operation frequency from the first operation frequency to the second operation frequency comprises:
controlling, in the rising duration, a duty cycle of a signal amplitude pulse to increase from 0 to a target duty cycle; and
controlling, in the falling duration, a duty cycle of a signal amplitude pulse to decrease from the target duty cycle to 0.

14. An operation method of a wireless power transmitter, the operation method comprising:
controlling the wireless power transmitter to operate at a first operation frequency;
changing an operation frequency of the wireless power transmitter from the first operation frequency to a second operation frequency based on a signal amplitude of the first operation frequency or a phase of the first operation frequency at an end timepoint of a channel duration, wherein the channel duration is a cycle of changing an operation frequency of the wireless power transmitter; and
controlling the wireless power transmitter to operate at the second operation frequency.

15. A wireless power transmitter comprising:
a controller configured to:
control the wireless power transmitter to operate at a first operation frequency included in an operation frequency set;
change an operation frequency of the wireless power transmitter from the first operation frequency to a second operation frequency that is different from an operation frequency of a second wireless power transmitter that is adjacent to the wireless power transmitter for every channel duration; and
control the wireless power transmitter to operate at the second operation frequency, and
a transmitting coil configured to transmit power at the first operation frequency or the second operation frequency.

16. The wireless power transmitter of claim 15, wherein the controller is configured to:
change the operation frequency from the first operation frequency to the second operation frequency using an orthogonal sequence.

17. The wireless power transmitter of claim 15, wherein the controller is configured to:
change the operation frequency from the first operation frequency to the second operation frequency based on a phase of the first operation frequency and a phase of the second operation frequency.

18. The wireless power transmitter of claim 17, wherein the controller is configured to:
track the phase of the first operation frequency during the channel duration; and
match an end phase of the first operation frequency with a start phase of the second operation frequency when the operation frequency is changed from the first operation frequency to the second operation frequency.

19. The method of claim 15, wherein the controller is configured to:
change the operation frequency from the first operation frequency to the second operation frequency based on a signal amplitude of the first operation frequency and a signal amplitude of the second operation frequency.

20. The method of claim 19, wherein the controller is configured to:
match an end signal amplitude of the first operation frequency and a start signal amplitude of the second operation frequency to 0.
